(19) United States
(12) Patent Application Publication
(10) Pub. No.: US 2007/0235812 A1
(43) Pub. Date: Oct. 11, 2007

(54) Semiconductor device and method for manufacturing the same

(76) Inventors: Hideaki Fujiwara, Hashima-shi (JP); Kazunori Fujita, Yoro-Gun (JP); Yoshikazu Yamaoka, Ogaki-shi (JP); Hideki Mizuhara, Ichinomiya-city (JP); Yasunori Inoue, Ogaki-city (JP)

Correspondence Address: MCDERMOTT WILL & EMERY LLP, 600 13TH STREET, N.W., WASHINGTON, DC, 20005-3096, US

(21) Appl. No.: 11/729,972

(22) Filed: Mar. 30, 2007

(30) Foreign Application Priority Data
Mar. 31, 2006 (JP) 2006-097066
Feb. 16, 2007 (JP) 2007-037169

(51) Int. Cl. H01L 23/62

(52) U.S. Cl. 257/360

(57) ABSTRACT

A semiconductor device operating at low voltage is provided where a threshold voltage is controlled with ease. A semiconductor substrate is element-isolated by element isolation regions. A source region and a source region are spaced from each other on the semiconductor substrate. A gate electrode is formed between the source region and the drain by way of a gate insulator. A plurality of insulating particles are embedded in the gate electrode in a scattered manner at an interface between the gate insulator and the gate electrode, where the particles are in contact with the gate insulator.

### BACKGROUND OF THE INVENTION

1. Field of the Invention

The present invention relates to a semiconductor device capable of operating at low voltage and a manufacturing method therefor.

2. Description of the Related Art

In recent years, demand is growing for electronic equipment, such as mobile phones, PDAs, DVCs and DSCs, to be not only more functionally sophisticated (e.g., multifunctional) but also smaller in size and more power-saving. To lower the power consumption of electronic equipment, it is essential that the power consumption of large scale integration circuits (LSIs) incorporated in such electronic equipment be held low. To reduce the power consumption of LSIs, it is necessary that the semiconductor devices that constitute each LSI be made less power-consuming. And to make a semiconductor device less power-consuming, the operating voltage of the semiconductor device must be lowered, and this requires a technology for lowering the threshold voltage of the semiconductor device.

Thus, as the operating voltage of the semiconductor device has been made lower, the thickness of gate insulator (EOT: Equivalent Oxide Thickness) has approached about 1 nm. A problem with this trend, however, is that for a conventional polysilicon gate electrode, a depleted layer is formed on a gate electrode side and thus the gate insulator is effectively thickened. To solve this problem, there has been technology development to use metal for the gate electrode.

Related Art List

(1) Japanese Patent Application Laid-Open No. 2000-068507.

The metal gate without depletion, which is the problem with the polysilicon gate, makes it possible to avoid the effective increase in gate insulator thickness due to depletion. However, the metal gate has it own problem in that it does not allow easy control of the threshold voltage.

### SUMMARY OF THE INVENTION

The present invention has been made to solve such problems, and a general purpose thereof is to provide a technology for making the operating voltage of a semiconductor device lower and at the same time making the control of a threshold voltage easier.

One embodiment of the present invention relates to a semiconductor device. This semiconductor device comprises: a semiconductor substrate; a source region and a drain region formed on the semiconductor substrate; a gate electrode formed between the source region and the drain by way of a gate insulator; and a plurality of insulating particles, embedded in the gate electrode in a scattered manner at interface between the gate insulator and said gate electrode and in contact with the gate insulator. Here, the form of silicon nitride particles is not subject to any particular limitation. And it may be spherical or polygonal or in an island-like thin film or a partially holed sheet not really forming a layer.

According to this embodiment, carriers mainly go in and out of a carrier trap formed at the interface between the gate insulator and the silicon nitride particles, from a gate electrode side. As a result, an electric charge is maintained at the interface between the gate insulator and the silicon nitride particles, without a tunnel current delivered, so that the threshold voltage and the effective capacity of the gate can be changed at low voltage. Utilizing this, conceivable is an application to a MOSFET where the threshold voltage is set higher by 0.1 to 0.2 V in the case of a low-voltage operation memory or in the neighborhood of the threshold voltage so as to suppress the off-leak current and, with a supply voltage applied to the gate, the device changes to a low-threshold-voltage FET so as to increase a saturation current.

In the above-described embodiment, a metal may be interposed partially between the insulating particles and the gate insulator. According to this embodiment, the amount of electric charge retained at the interface between the gate insulator and the silicon nitride particles can be increased, so that the threshold voltage of the semiconductor device and the effective capacitance change of the gate can be maintained for a long time.

In the above-described embodiment, an average particle diameter of the insulating particle may be approximately 1 to 5 nm. Also, the insulating particle may be a combination of one or more materials selected from a group of high-k materials including silicon nitride, Hf oxide, Al oxide, Zr oxide and lanthanum oxide.

Another embodiment of the present invention relates to a method of manufacturing a semiconductor device. This method for manufacturing a semiconductor device comprises: forming a gate insulator on a semiconductor substrate provided between a source region and a drain region; scattering a plurality of insulating particles on the gate insulating film; and forming a gate electrode above the gate insulator.

Still another embodiment of the present invention relates also to a method of manufacturing a semiconductor device. This method for manufacturing a semiconductor device comprises: forming a gate insulator on a semiconductor substrate provided between a source region and a drain region; scattering a plurality of metal particles on the gate insulating film; scattering a plurality of insulating particles and interposing the metal particles between one or more insulating particles and the gate insulator; forming a gate electrode above the gate insulator.

In either one of the above-described methods, an average particle diameter of the plurality of insulating particles may be approximately 1 to 5 nm. The insulating particle may be a combination of one or more materials selected from a group of high-k materials including silicon nitride, Hf oxide, Al oxide, Zr oxide and lanthanum oxide.

The above-described semiconductor device may be used as a memory device that differentiates a state by making use of a difference in an electric charge retained in an interface between the gate insulator and the insulating particles. In such a case, a drain region of the memory device mutually insulated from a memory device adjacent thereto by an element isolation region may be connected to a drain of the adjacent memory device thereto via a diode structure.

It is to be noted that any arbitrary combinations or rearrangement, as appropriate, of the aforementioned constituting elements and so forth are all effective as and encompassed by the embodiments of the present invention.

Moreover, this summary of the invention does not necessarily describe all necessary features so that the invention may also be sub-combination of these described features.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 is a cross-sectional view illustrating a structure of a semiconductor device according to a first embodiment of the present invention;

FIG. 2 is a graph showing the CV characteristic of a gate insulator accompanied by silicon nitride particles;

FIGS. 3A to 3E are process sectional views showing a method for manufacturing a semiconductor according to a first embodiment of the present invention;

FIG. 4 is a cross-sectional view illustrating a structure of a semiconductor device 11 according to a second embodiment of the present invention;

FIG. 5 is a feature sectional view illustrating a gate structure of a semiconductor device according to a second embodiment of the present invention;

FIG. 6 is a feature sectional view illustrating a gate structure of a semiconductor according to a second embodiment of the present invention; and

FIG. 7 is a cross-sectional view of a semiconductor device when it is used as a memory device.

### DETAILED DESCRIPTION OF THE INVENTION

The invention will now be described by reference to the preferred embodiments. This does not intend to limit the scope of the present invention, but to exemplify the invention.

### First Embodiment

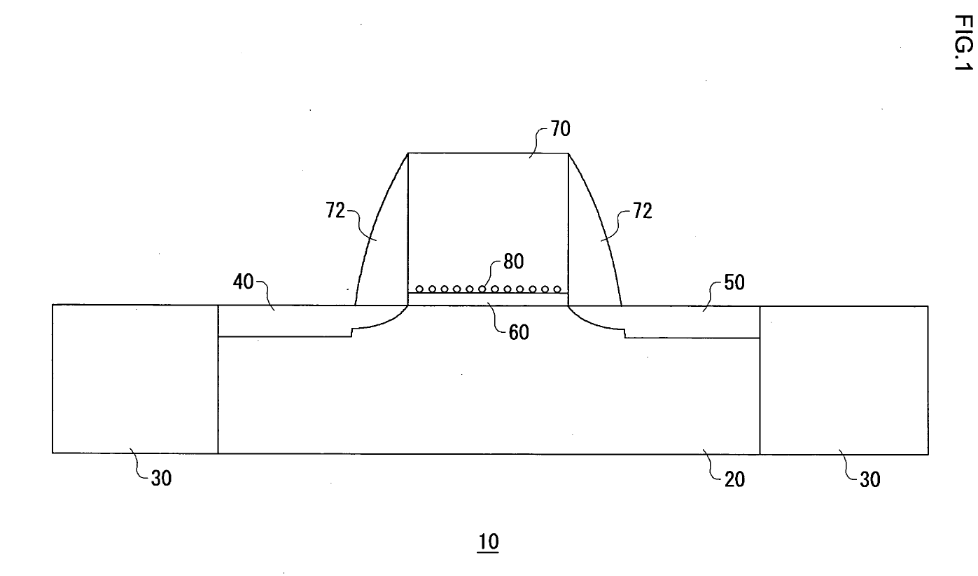

FIG. 1 is a cross-sectional view illustrating a structure of a semiconductor device 10 according to a first embodiment of the present invention. A semiconductor substrate 20 is element-isolated by element isolation regions 30 using STI (shallow trench isolation) 30. A silicon substrate, for instance, may be used as the semiconductor substrate 20. Disposed within the element-isolated semiconductor substrate 20 are a source region 40 and a drain region 50 spaced from each other. Between the source region 40 and the drain region 50, a gate electrode 70 is formed with the medium of a gate insulator 60, which is a silicon oxide film. Side walls 72 are provided on the sides of the gate insulator 60 and the gate electrode 70.

A plurality of silicon nitride particles 80 are scatteringly embedded in the gate electrode, in contact with the gate insulator 60, at the interface between the gate insulator 60 and the gate electrode 70. The average particle diameter of the plurality of silicon nitride particles 80 is preferably 1 to 5 nm.

In this arrangement, carriers from the gate electrode 70 side go in and out of the carrier trap formed at the interface between the gate insulator 60 and silicon nitride particles 80. As a result, an electric charge is maintained at the interface between the gate insulator 60 and the silicon nitride particles 80, so that the threshold voltage and the effective capacity of the gate can be changed at low voltage.

In the present embodiment, silicon nitride particles are used as insulating particles present on the interface between the gate insulator 60 and the gate electrode 70. However, the insulating particles are not limited thereto and a high-k material where a level or trapping occurs on the interface may be used. For example, the insulating particles may be Hf oxides such as HfO₂, HfAlO and HfON, Al oxides such as Al₂O, Zr oxides such as ZrO₂, or lanthanum oxides such as La₂O₃. Also, the insulating particle may be a combination of one or more above-described compounds.

CV Characteristic Evaluation

The CV characteristic of the gate insulator accompanied by the silicon nitride particles of a semiconductor device according to the present embodiment was measured using a mercury probe (Hg-CV/IV measuring unit made by SSM Japan K.K.). A film structure with silicon nitride particles deposited on a silicon oxide film of 3.2 nm in thickness was used as the sample.

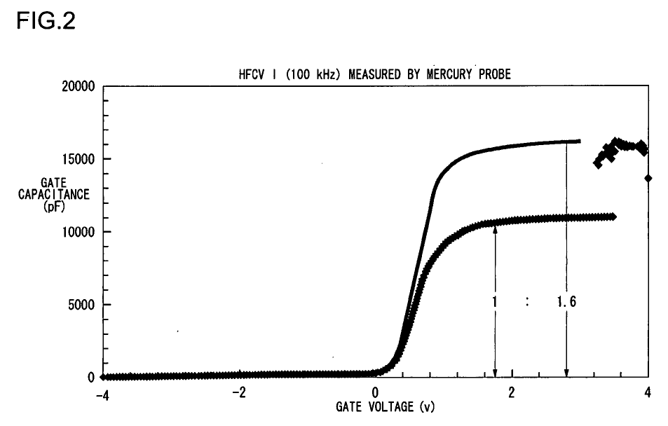

FIG. 2 is a graph showing the CV characteristic of a gate insulator accompanied by silicon nitride particles. As shown in FIG. 2, as the gate voltage rises from 0 V, the gate capacitance increases, and then as the gate voltage is further raised, the gate voltage reaches a saturation point and thereafter stays approximately at a constant level. The gate capacitance at this saturation point is regarded here as 1 (reference value). Then, after the gate voltage is raised to +4 V, the gate voltage is lowered gradually, which results in a gate capacitance 1.6 times the above-mentioned reference value. The state in which the gate capacitance is relatively low is assumed to be a state of reduced gate capacitance or increased gate threshold value, which results from the trapping of electric charge at the interface between the silicon oxide film and the silicon nitride when the gate voltage is set below −3 to −4 V (inclusive). The electric charge trapped at the interface between the silicon oxide film and the silicon nitride gets released as the gate voltage is raised above +4 V (inclusive), and the gate capacitance increases precipitously. Therefore, the semiconductor device according to the present embodiment, which has a function of charge retention by the gate insulator with silicon nitride particles attached thereto, is applicable as memory.

Manufacturing Method

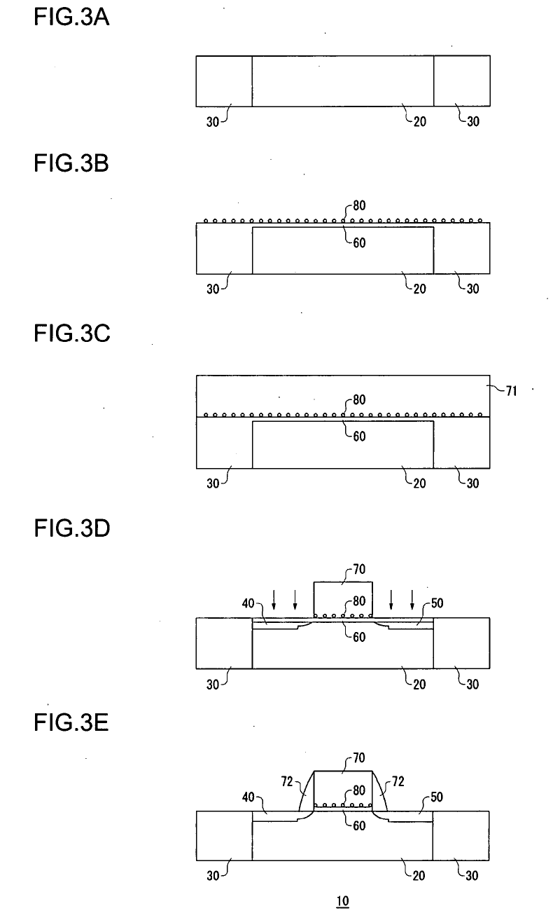

A manufacturing method of a semiconductor device 10 according to the first embodiment will be described by referring to the process sectional views of FIGS. 3A to 3E. Firstly, as illustrated in FIG. 3A, an element isolating region 30, which is designed to electrically isolate the element from the others using STI, is formed around an element-forming region (active region) within a semiconductor substrate 20. Note that use of LOCOS for isolating elements from each other may realize further reduction in cost.

Next, as illustrated in FIG. 3B, after forming a gate insulator 60, comprised of a 3.2-nm-thick silicon oxide film, by thermally oxidizing the region element-isolated by the element isolating region 30, a plurality of silicon nitride particles 80 of 1 to 5 nm in average particle diameter are scattered over the gate insulator 60 by an LPCVD method (deposition at 650 to 700° C. for about 20 minutes). It is to be noted that the form of silicon nitride particles is not subject to any particular limitation; it may be spherical or polygonal or in an island-like thin film or a partially holed sheet not really forming a layer.

Next, as illustrated in FIG. 3C, a film of polysilicon 71 is formed on the whole surface of the semiconductor substrate 20 by a CVD method. A typical film thickness of polysilicon 71 is 150 nm.

Next, as illustrated in FIG. 3D, a gate electrode 70 is formed by selectively removing the polysilicon 71 and the silicon nitride particles by photolithography and dry etching techniques in such a manner as to leave the gate-forming region. Then phosphorus or the like is ion-implanted into a source region 40 and a drain region 50.

Next, as illustrated in FIG. 3E, after forming an insulating film made of silicon oxide, the silicon oxide film over the source region 40 and the drain region 50 is removed by an anisotropic dry etching, and at the same time a side wall 72 is formed. Then arsenic is ion-implanted into the source region 40 and the drain region 50.

Through the process as described above, a semiconductor device 10 capable of operating at low voltage can be manufactured easily. Note that while the above process is equal to the manufacturing method for an n-type MOSFET, a p-type MOSFET may also be manufactured by a similar process. Moreover, a CMOS structure may be manufactured using the above-described process as the basic process.

In the above-described method for manufacturing a semiconductor device, silicon nitride particles are used as insulating particles present on the interface between the gate insulator 60 and the gate electrode 70. However, the insulating particles are not limited thereto and a high-k material where a level or trapping occurs on the interface may be used. For example, the insulating particles may be Hf oxides such as HfO₂, HfAlO and HfON, Al oxides such as Al₂O, Zr oxides such as ZrO₂, or lanthanum oxides such as La₂O₃. Also, the insulating particle may be a combination of one or more above-described compounds. Note that SiO₂ particles may be formed on a high-k film such as SiN and HfOₓ.

### Second Embodiment

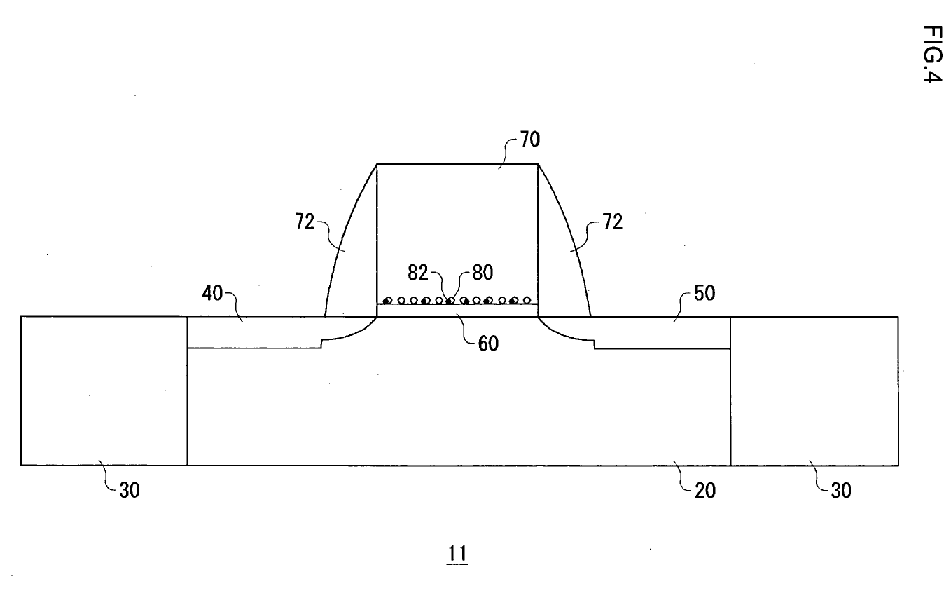

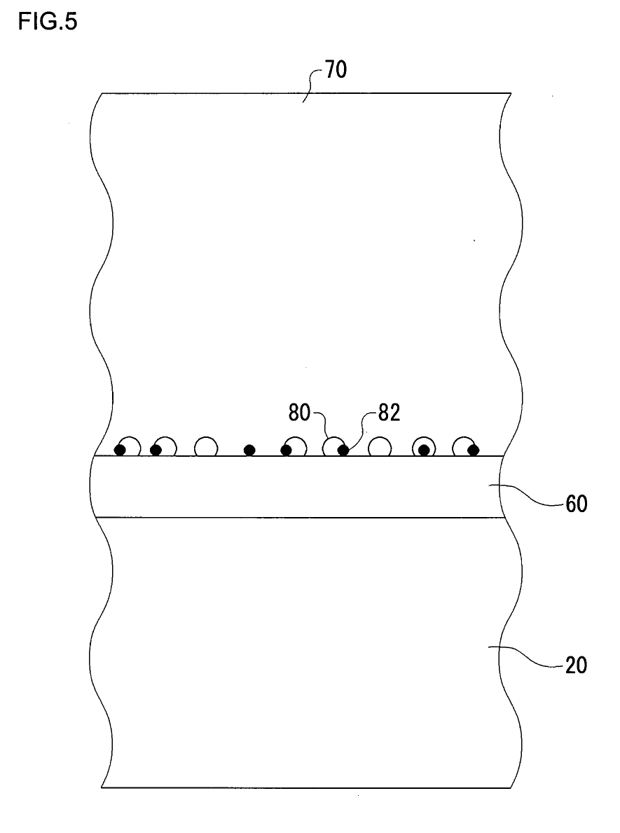

FIG. 4 is a cross-sectional view illustrating a structure of a semiconductor device 11 according to a second embodiment of the present invention. FIG. 5 is a feature sectional view illustrating a gate structure of a semiconductor device 11 according to the second embodiment. The semiconductor device 11 has the same structure as the semiconductor device 10 according to the first embodiment except that it has metal particles 82 partially interposed between silicon nitride particles 80 and gate insulator 60. The metal particles are preferably TiN or TaN. This arrangement can increase the amount of electric charge retained at the interface between the gate insulator 60 and the silicon nitride particles 80, so that the threshold voltage of the semiconductor device and the effective capacitance change of the gate can be maintained for a long time.

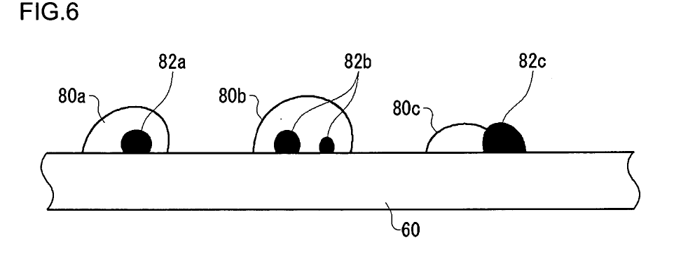

The manufacturing method for a semiconductor device 11 according to the second embodiment is the same as that for a semiconductor device 10 according to the first embodiment except the process as illustrated in FIG. 3B. According to the manufacturing method for a semiconductor device 11 according to the second embodiment, metal particles 82 are scattered in advance over the gate insulator 60 before the silicon nitride particles 80 are scattered thereon in the process of FIG. 3B. This allows the metal particles 82 to be partially interposed between the silicon nitride particles 80 and the gate insulator 60. Instead of using an LPCVD method, the silicon nitride particles 80 and the metal particles 82 partially covering the gate insulator 60 can be formed in a manner such that they are agglomerated by performing a heat thermal treatment thereon (for example, at 600° C. for about 30 minutes) after subjecting them to the sputtering. Note that it is not always necessary that the metal particles 82 and the silicon nitride particles 80 are in a one-to-one correspondence with each other. There may be silicon nitride particles 80 in direct contact with the gate insulator 60 without the intermediation of metal particles 82. Moreover, as shown in FIG. 6, a metal particle 82a in contact with a gate insulator 60 may be contained within a silicon nitride particle 80a on the gate insulator 60. Also, a plurality of metal particles 82b in contact with the gate insulator 60 may be contained within a silicon nitride particle 80b on the gate insulator 60. In this manner, the metal particle or particles can be confined within the silicon nitride particle, thus improving the long-term reliability. Also, a side face of a silicon nitride particle 80c on the gate insulator 60 may come in contact with a metal particle 82c on the gate insulator 60.

Similar to the first embodiment, the above-described various high-k materials may be used in place of he silicon nitride particles 80.

### Third Embodiment

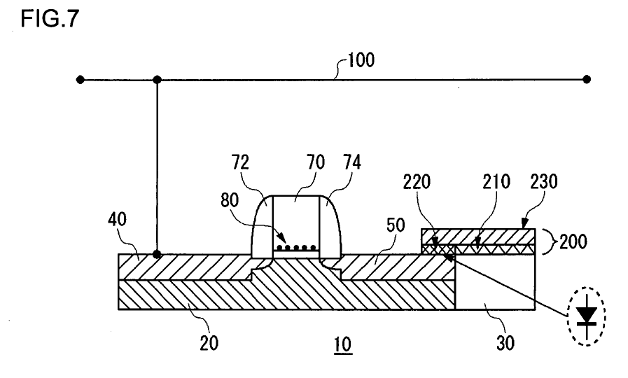

FIG. 7 is a cross-sectional view of a semiconductor device when it is used as a memory device. The basic components in a semiconductor device 10 is the same as those shown in the first embodiment, so that the same components as those in the first embodiment are given the same reference numerals as those in the first embodiment and the description thereof is omitted as appropriate. The semiconductor device 10 shown in FIG. 7 is a selected cell where a write or read is performed. A selected cell shares the gate thereof with an unselected cell (not shown) where write or read is not performed. A source region 40 is connected with a source line 100. A drain region 50 is connected to a drain of an adjacent cell (semiconductor device) having the gate electrode in common with the selected cell, via a diode structure 200 formed on the element isolation region 30.

The diode structure 200 according to the present embodiment is a Schottky barrier comprised of a Ti layer 210 formed on an element isolation region 30, a TiSi2 layer 220 formed on the drain region 50, in contact with a Ti layer 210, and a TiN layer 230 formed on the Ti layer 210 and the TiSi2 layer 220. Thereby, the direction of the current flowing from the source region of the unselected cell to the drain region of the selected cell can be set to one direction. Note that the diode structure is not limited thereto and, for example, a TiN/TiO₂ interface may be used.

The following Table 1 shows combinations of a source voltage, a gate voltage and a drain voltage when a write or read is performed on a selected cell.

TABLE 1

| | SOURCE | GATE | DRAIN |
|---|---|---|---|
| OPERATING STATE | VOLTAGE | VOLTAGE | VOLTAGE |
| DELETION | 0 V | −5 V | 0 V |
| WRITE (SELECTED CELL) | 0 V | 5 V | 0 V |
| (UNSELECTED CELL) | 5 V | 5 V | 0 V |
| READOUT (SELECTED | 0 V | 3 V | 3 V |
| CELL) | | | |
| (UNSELECTED CELL) | Floating | 3 V | 3 V |

If the operation state of a selected cell (as well as an unselected cell) is to be deleted, the source voltage, the gate voltage and the drain voltage will be set to 0 V, −5 V and 0 V, respectively. As a result, the electric charge is trapped in the interface between the silicon oxide film and the silicon nitride, and a state of reduced gate capacitance or increased gate threshold voltage is created.

If a write is to be performed on the selected cell, the source voltage, the gate voltage and the drain voltage of the selected cell will be set to 0 V, 5 V and 0 V, respectively, and those voltages of the unselected cell will be set to 5 V, 5 V and 0 V, respectively. This releases the electric charge trapped in the interface between the silicon oxide film and the silicon nitride, which in turn results in a gate capacitance 1.6 times the reference value. This is equivalent to the state in which the gate capacitance is relatively low.

Next, if a readout is performed, the source voltage, the gate voltage and the drain voltage of the selected cell will be set to 0 V, 3 V and 3 V, respectively, and those voltages of the unselected cell will be set to “floating”, 3 V and 3 V, respectively. At this time, if a write has already been performed in the selected cell, the current will flow. However, if the selected cell has been deleted, the current will not flow or the current will be much less. As a result, the state of a cell can be distinguished between “1” and “0”. On the other hand, if the source voltage is set to “floating”, the current will not flow regardless of the cell state and therefore the state is retained intact.

While the preferred embodiments of the present invention have been described using specific terms, such description is for illustrative purposes only, and it is to be understood that changes and variations may be made without departing from the spirit or scope of the appended claims.

What is claimed is:

1. A semiconductor device, comprising:
a semiconductor substrate;
a source region and a drain region formed on said semiconductor substrate;
a gate electrode formed between said source region and said drain by way of a gate insulator; and
a plurality of insulating particles, embedded in said gate electrode in a scattered manner at an interface between the gate insulator and said gate electrode, the particles being in contact with the gate insulator.

2. A semiconductor device according to claim 2, wherein a metal is interposed partially between said insulating particles and the gate insulator.

3. A semiconductor device according to claim 1, wherein an average particle diameter of said insulating particle is approximately 1 to 5 nm.

4. A semiconductor device according to claim 2, wherein an average particle diameter of said insulating particle is approximately 1 to 5 nm.

5. A semiconductor device according to claim 1, wherein said insulating particle is a combination of one or more materials selected from a group of high-k materials including silicon nitride, Hf oxide, Al oxide, Zr oxide and lanthanum oxide.

6. A semiconductor device according to claim 2, wherein said insulating particle is a combination of one or more materials selected from silicon nitride or a group of high-k materials including Hf oxide, Al oxide, Zr oxide and lanthanum oxide.

7. A semiconductor device according to claim 3, wherein said insulating particle is a combination of one or more materials selected from silicon nitride or a group of high-k materials including Hf oxide, Al oxide, Zr oxide and lanthanum oxide.

8. A method of manufacturing a semiconductor device, the method comprising:
forming a gate insulator on a semiconductor substrate provided between a source region and a drain region;
scattering a plurality of insulating particles on the gate insulating film; and
forming a gate electrode above the gate insulator.

9. A method of manufacturing a semiconductor device, the method comprising:
forming a gate insulator on a semiconductor substrate provided between a source region and a drain region;
scattering a plurality of metal particles on the gate insulating film;
scattering a plurality of insulating particles and interposing the metal particles between one or more insulating particles and the gate insulator;
forming a gate electrode above the gate insulator.

10. A semiconductor manufacturing method according to claim 8, wherein an average particle diameter of the plurality of insulating particles is approximately 1 to 5 nm.

11. A semiconductor manufacturing method according to claim 9, wherein an average particle diameter of the plurality of insulating particles is approximately 1 to 5 nm.

12. A semiconductor manufacturing method according to claim 8, wherein the insulating particle is a combination of one or more materials selected from silicon nitride or a group of high-k materials including Hf oxide, Al oxide, Zr oxide and lanthanum oxide.

13. A semiconductor manufacturing method according to claim 9, wherein the insulating particle is a combination of one or more materials selected from silicon nitride or a group of high-k materials including Hf oxide, Al oxide, Zr oxide and lanthanum oxide.

14. A semiconductor manufacturing method according to claim 10, wherein the insulating particle is a combination of one or more materials selected from silicon nitride or a group of high-k materials including Hf oxide, Al oxide, Zr oxide and lanthanum oxide.

15. A semiconductor device according to claim 1, wherein said semiconductor device is used as a memory device that differentiates a state by making use of a difference in an electric charge retained in an interface between the gate insulator and the insulating particles.

16. A semiconductor device according to claim 2, wherein said semiconductor device is used as a memory device that differentiates a state by making use of a difference in an electric charge retained in an interface between the gate insulator and the insulating particles.

17. A semiconductor device according to claim 3, wherein said semiconductor device is used as a memory device that differentiates a state by making use of a difference in an electric charge retained in an interface between the gate insulator and the insulating particles.

18. A semiconductor device according to claim 15, wherein a drain region of the memory device mutually insulated from a memory device adjacent thereto by an element isolation region is connected thereto via a diode structure.

19. A semiconductor device according to claim 16, wherein a drain region of the memory device mutually insulated from a memory device adjacent thereto by an element isolation region is connected thereto via a diode structure.

20. A semiconductor device according to claim 17, wherein a drain region of the memory device mutually insulated from a memory device adjacent thereto by an element isolation region is connected thereto via a diode structure.
